(19) United States
(12) Patent Application Publication
(10) Pub. No.: US 2026/0343816 A1
(43) Pub. Date: Oct. 29, 2026

(54) HEAT EXCHANGER ASSEMBLY

(71) Applicant: ASIA VITAL COMPONENTS (CHINA) CO., LTD., Shenzhen (CN)

(72) Inventors: Han-Min Liu, Shenzhen (CN); Xiao-Xiang Zhou, Shenzhen (CN)

(21) Appl. No.: 19/234,571

(22) Filed: Jun. 11, 2025

(30) Foreign Application Priority Data
Apr. 25, 2025 (TW) 114115806

(51) Int. Cl. H05K 7/20

(52) U.S. Cl. CPC H05K 7/20318; H05K 7/20309

(57) ABSTRACT

A heat exchanger assembly includes at least one condenser structure, which includes a top cover provided on an inner side surface with a plurality of first columns and a bottom plate provided on an inner side surface with a plurality of second columns. The top cover and the bottom plate are closed together to define a sealed chamber between them. A working fluid is filled in the sealed chamber. The first columns have end surfaces located corresponding to and shaped complementary to end surfaces of the second columns. With these arrangements, the heat exchanger assembly can be used in a special environment, such as an extremely low-temperature environment, while the condenser structure thereof would not become swollen and damaged when the working fluid vapor freezes to have an expanded volume in the condenser structure.

This application claims the priority benefit of Taiwan patent application number 114115806 filed on Apr. 25, 2025, the disclosure of which is hereby incorporated by reference in its entirety.

### FIELD OF THE INVENTION

The present invention relates to a heat exchanger assembly, and more particularly, to a heat exchanger assembly that can be used in a special environment.

### BACKGROUND OF THE INVENTION

The currently available compact and highly integrated electronic devices all have a significantly high heat flux density across their internal chips. In this case, a heat exchanger utilizing phase transition such as two-phase flow is widely employed for its high efficiency in heat dissipation.

FIG. 1 is a fragmentary, enlarged sectional view of a condenser structure 9 commonly used in a conventional heat exchanger assembly. As shown, the condenser structure 9 includes a top cover 911 and a bottom plate 912, which are closed together to define a sealed chamber 92 between them. A working fluid circulates in the sealed chamber to achieve the effect of heat exchanging. For instance, a plurality of supporting columns 93 can be provided in the sealed chamber 92 defined between the closed top cover 911 and bottom plate 912 to provide the top cover 911 and the bottom plate 912 with required structural supporting strength.

The condenser structure 9 in the conventional heat exchanger assembly (not shown) is connected to an evaporator, which is in contact with a heat source such as an electronic device, via an inlet pipe for guiding vaporized working fluid to flow through and a backflow pipe for guiding condensed working fluid to flow through. In this case, an inner side surface of the top cover 911 and an inner side surface of the bottom plate 912 shall respectively serve as one of a backflow side and a condensing side. The supporting columns 93 are usually provided on the inner side surface of one of the top cover 911 and the bottom plate 912 with their end surfaces extending toward another one of the top cover 911 and the bottom plate 912 to connect to or contact the inner side surface of the bottom plate 912, such that a gap is formed between the inner side surface of the top cover 911 or the bottom plate 912 and each of the end surfaces of the supporting columns 93. Alternatively, the supporting columns 93 can be provided in the sealed chamber 92 with a gap formed between both end surfaces of the supporting columns 93 and the inner side surfaces of the top cover 911 and the bottom plate 912.

In the above conventional condenser structure 9, no matter the gaps are formed near the backflow side or the condensing side, the working fluid circulating in the sealed chamber 92 would flow through the gaps between the end surfaces of the supporting columns 93 and the inner side surface of the top cover 911 and/or the bottom plate 912. When the conventional heat exchanger assembly is used in a special environment, such as an extremely low-temperature environment, the working fluid, such as water, might freeze under the extremely low temperature. When the working fluid builds up at the gaps and freezes to have an expanded volume, it will weaken the structural strength of the supporting columns 93 and cause swollen top cove 911 and bottom plate 912, or even result in a system failure. For example, when vapor of the working fluid in the condenser structure 9 used in an extremely low-temperature environment flows through the condensing side, the vapor might freeze in the gaps at the condensing side due to the low temperature. Or, the working fluid built up at the backflow side might freeze in the gaps at the backflow side under the extremely low temperature.

Therefore, for an electronic device used in a special environment such as in an extremely low-temperature environment, although the conventional heat exchanger assembly can provide pretty good heat transfer, it has the problem that the working fluid, such as water, used in the condenser structure 9 of the heat exchanger assembly tends to freeze under low temperature to cause swollen condenser structure 9. It is therefore tried by the inventor to solve the above problem in the conventional heat exchanger assembly.

### SUMMARY OF THE INVENTION

To effectively solve the above mentioned problem, a primary object of the present invention is to provide a heat exchanger assembly, which can be used in a special environment.

To achieve the above and other objects, the heat exchanger assembly of the present invention includes at least one condenser structure, which has a top cover and a bottom plate.

The top cover is provided on an inner side surface of the top cover with a plurality of first columns, and the bottom plate is provided on an inner side surface of the bottom plate with a plurality of second columns. The top cover and the bottom plate are closed to each other to define a sealed chamber between them. The first and the second columns are located in the sealed chamber with their end surfaces located end to end in one to one correspondence.

When the heat exchanger assembly according to the present invention is used in a special environment, such as an extremely low-temperature environment, the condenser structure would not become swollen and damaged due to an expanded volume of a working fluid frozen in the sealed chamber.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a fragmentary, enlarged sectional view of a conventional condenser structure;

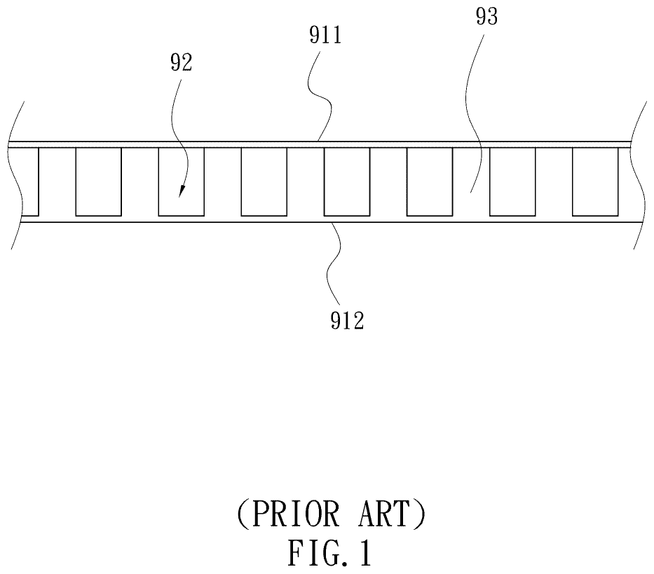

FIG. 2 is an assembled perspective view of a heat exchanger assembly according to a preferred embodiment of the present invention;

FIG. 3 is an exploded top perspective view of a condenser structure for the heat exchanger assembly of FIG. 2;

FIG. 4 is an exploded bottom perspective view of the condenser structure of FIG. 3;

FIG. 5 is an exploded sectional side view of the condenser structure for the heat exchanger assembly of FIG. 2;

FIG. 6 is an assembled view of FIG. 5;

FIG. 7 is an exploded sectional side view of a first variant of the condenser structure for the heat exchanger assembly of FIG. 2; and

FIG. 8 is an exploded sectional side view of a second variant of the condenser structure for the heat exchanger assembly of FIG. 2.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

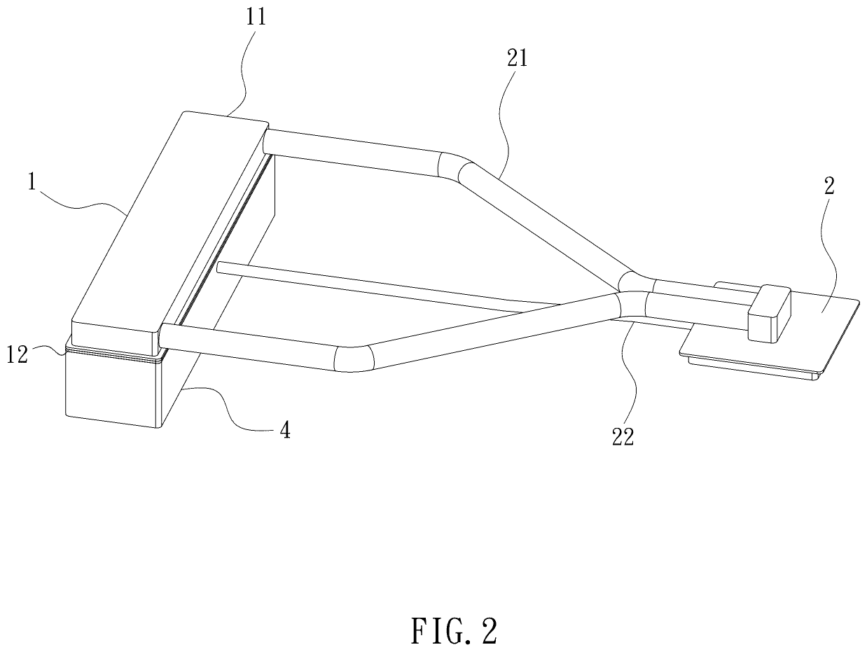

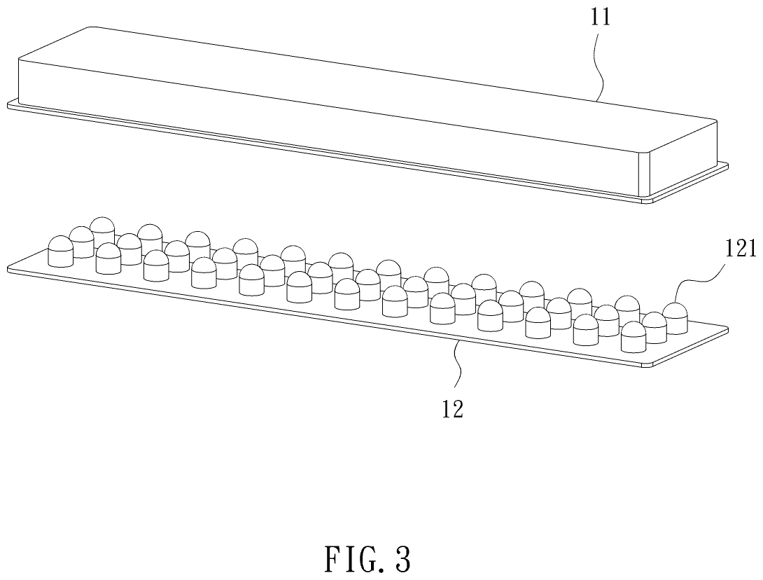

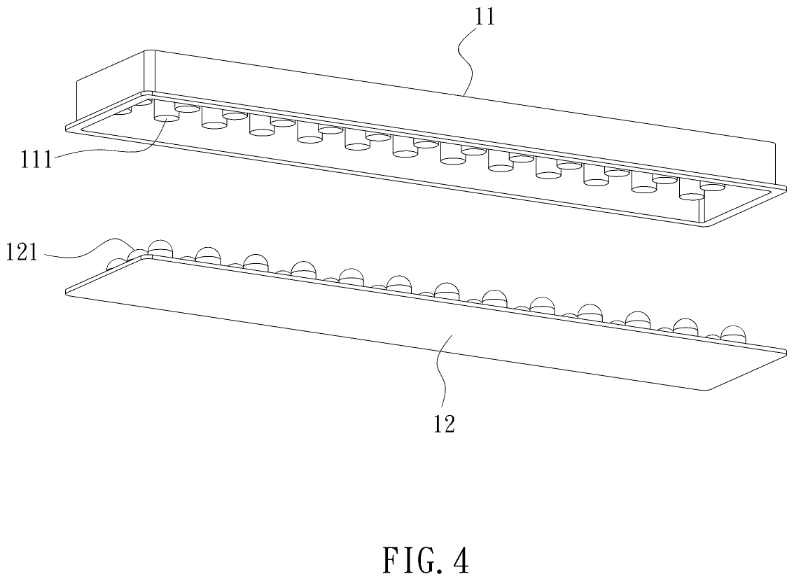

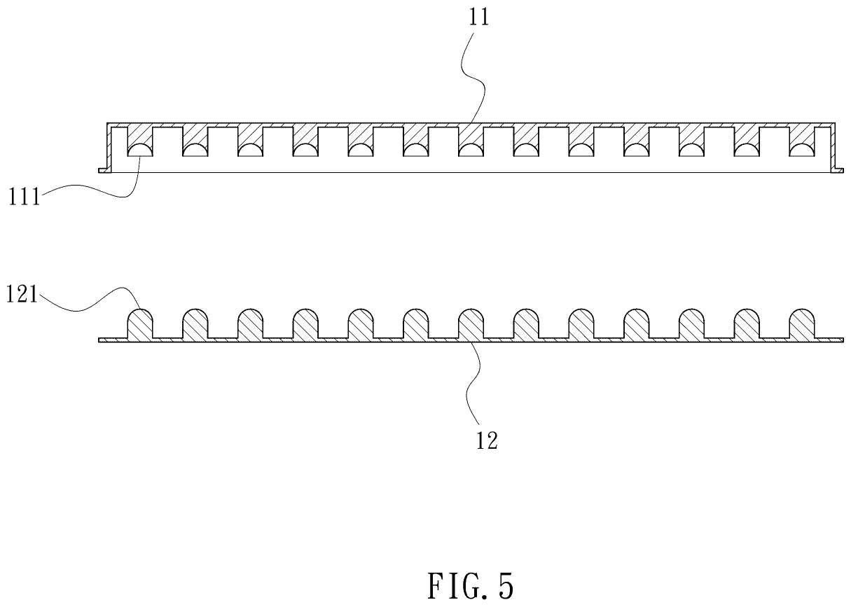

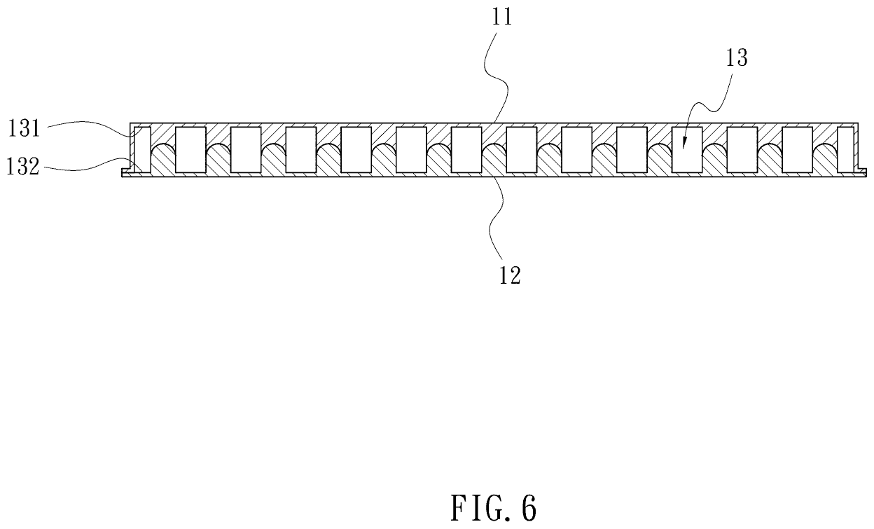

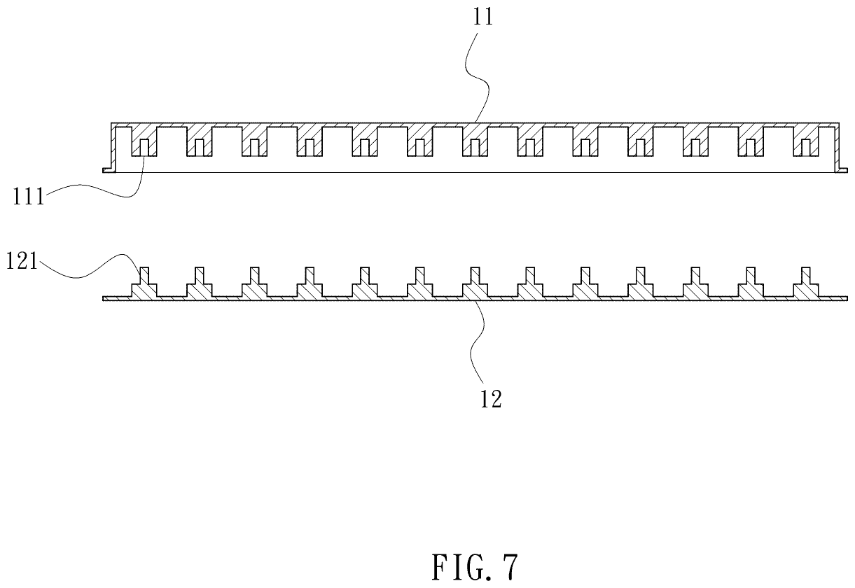

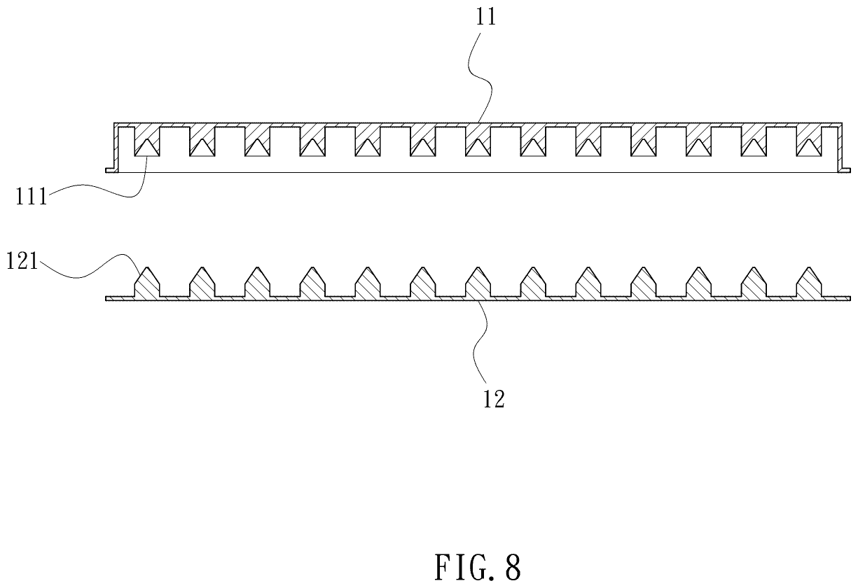

Please refer to FIG. 2, which is an assembled perspective view of a heat exchanger assembly according to a preferred embodiment of the present invention; to FIGS. 3 and 4, which are exploded top and bottom perspective views, respectively, of a condenser structure 1 for the heat exchanger assembly of FIG. 2; to FIGS. 5 and 6, which are exploded and assembled sectional side views, respectively, of the condenser structure 1 for the heat exchanger assembly of FIG. 2; and to FIGS. 7 and 8, which are exploded sectional side views of a first and a second variant, respectively, of the condenser structure 1 for the heat exchanger assembly of FIG. 2.

As can be seen from FIGS. 2 to 6, the heat exchanger assembly of the present invention includes at least one condenser structure 1, which includes a top cover 11 and a bottom plate 12. According to some embodiments, the top cover 11 and the bottom plate 12 all are made of a metal material with good thermal conductivity. Specifically, the top cover 11 and the bottom plate 12 can be closed together to define a sealed chamber 13 between them. A working fluid (not shown) is filled in the sealed chamber 13 to circulate therein to achieve the purpose of heat exchange.

Please refer to FIG. 2. In some embodiments, the heat exchanger assembly of the present invention can further include an evaporator 2 corresponding to the condenser structure 1. The evaporator 2 can be, for example, a water block, which can absorb heat energy produced by an electronic device and transfer the absorbed heat to the working fluid, so that phase transition occurs in the working fluid, that is, the working fluid is vaporized into a gas.

The evaporator 2 and the condenser structure 1 are communicable with each other via at least one inlet pipe 21 provided between them for delivering vaporized working fluid and at least one backflow pipe 22 provided between them for delivering condensed working fluid. The inlet pipe 21 and the backflow pipe 22 may be respectively, for example, a loop thermal siphon or a loop heat pipe. With these arrangements, the vaporized working fluid can be transported via the inlet pipe 21 to the condenser structure 1 and condensed. The condensed working fluid can be then transported via the backflow pipe 22 to the evaporator 2 and vaporized. The working fluid circulates in between the condenser structure 1 and the evaporator 2, and phase transition of the working fluid continues to achieve the purpose of heat exchange. The sealed chamber 13 has a condensing side 131 and a backflow side 132 designed corresponding to the circulation of the working fluid. The condensing side 131 is located at an upper side corresponding to the upward moving vaporized working fluid and can be provided close to the inlet pipe 21. The backflow side 132 is located opposite to the condensing side 131, and the condensed working fluid flows back under the force of gravity.

For example, as shown in FIG. 6, in the heat exchanger assembly with the above arrangements, the condensing side 131 of the sealed chamber 13 is located corresponding to an inner side surface of the top cover 11, and the backflow side 132 is located corresponding to an inner side surface of the bottom plate 12. However, the present invention is not necessarily limited to the above arrangements. In the preferred embodiment, the top cover 11 has an outer side surface facing upward and in contact with a low-temperature external environment for releasing heat in the process of heat exchange. Of course, the present invention can be implemented without being influenced by other arrangements correspondingly provided on the top cover 11 and the bottom plate 12 for forming the condensing side 131 and the backflow side 132.

And, as shown in FIG. 2, the heat exchanger assembly according to the preferred embodiment of the present invention can further include a radiation fin assembly (not shown) provided on an outer side surface of the bottom plate 12, and a fluid storage tank 4 located corresponding to and downward protruded from the backflow side 132 on the inner side surface of the bottom plate 12. The fluid storage tank 4 is communicable with the bottom plate 12 and the backflow pipe 22, such that the condensed and back flowed working fluid is guided by the fluid storage tank 4 and the backflow pipe 22 to flow back into the evaporator 2 for subsequent heat exchange and circulation of the working fluid in the heat exchanger assembly. Thus, the working fluid, such as water, circulates to achieve heat exchange through two-phase flow. In other words, the working fluid absorbs the heat energy produced by the electronic device and is vaporized, and the vaporized working fluid circulates and is condensed to release heat into the external environment.

In other embodiments of the heat exchanger assembly according to the present invention, it is also possible to include only the condenser structure 1 while all other structures mentioned above, such as the evaporator 2, are omitted from the heat exchanger assembly. In this case, the working fluid circulates only in the sealed chamber 13 to perform a closed heat exchange circulation, and the sealed chamber 13 functions like a vapor chamber, a three-dimensional vapor chamber, or a two-phase flow device (not shown). For instance, the electronic device can be so positioned that it is in direct contact with the outer side surface of the backflow side 132, such that the phase transition of the working fluid occurs directly at the backflow side 132 when the working fluid absorbs heat and is vaporized.

Particularly, the condenser structure 1 in the heat exchanger assembly of the present invention includes a plurality of first columns 111 arrayed on the inner side surface of the top cover 11 and a plurality of second columns 121 arrayed on the inner side surface of the bottom plate 12.

In the present invention, the first and the second columns 111, 121 can be integrally formed with the top cover 11 and the bottom plate 12 by way of press forging, casting or welding without being particularly limited thereto. Therefore, there is not any gap existed between the first columns 111 and the top cover 11 or between the second columns 121 and the bottom plate 12. Specifically, no gap will form at joints of the first columns 111 and the top cover 11 and joints of the second columns 121 and the bottom plate 12.

The heat exchanger assembly of the present invention can be used in a special environment, such as an extremely low-temperature environment, and the working fluid might get frozen on the inner side surface of the top cover 11 or the bottom plate 12. However, no matter how the condensing side 131 and the backflow side 132 are arranged corresponding to the top cover 11 and the bottom plate 12, no frozen working fluid will build up in any gap because the first columns 111 are integrally extended from the inner side surface of the top cover 11 toward the inner side surface of the bottom cover 12 without forming any gap on or near the inner side surface of the top cover 11 and similarly, the second columns 121 are integrally extended from the inner side surface of the bottom plate 12 toward the inner side surface of the top cover 11 without forming any gap on or near the inner side surface of the bottom plate 12. Since there is not any gap between the first/second columns 111, 121 and the top cover 11 or the bottom plate 12 for any frozen working fluid to build up therein, the frozen working fluid does not have any reverse influence on the structural strength of the first columns 111 and the second columns 121 or cause any swelling of the top cover 11 or the bottom plate 12 that might result in a system failure.

It is noted that, in the present invention, the top cover 11 and the bottom plate 12 are closed to each other to define the sealed chamber 13 between them, and the first columns 111 and the second columns 121 extended from the top cover 11 and the bottom plate 12 are located end to end in one to one correspondence. End surfaces of the first and the second columns 111, 121 can be formed in different shapes. In an embodiment, both the first and the second columns 111, 121 have flat end surfaces. In an example, the end surfaces of one of the first columns 111 and the second columns 121 have a protruded configuration, while the end surfaces of the other one have a recessed configuration complementary to the aforesaid protruded configuration. Alternatively, the end surfaces of one of the first columns 111 and the second columns 121 can be in a certain geometrical shape, while the end surfaces of the other one are in another geometrical shape corresponding to or matching the foresaid geometrical shape. As shown in FIGS. 6, 7, and 8, the recessed and the protruded end surfaces of the first and the second columns 111, 121, respectively, can have complementary profiles being a curved profile, a rectangular profile, or a wedge-shaped profile to be correspondingly engaged with each other.

Please refer to FIGS. 2 to 6 again. In the illustrated preferred embodiment of the present invention, according to the position of the condenser structure 1 relative to the evaporator 2, the inlet pipe 21, the backflow pipe 22, and the flow storage tank 4, the condensing side 131 is located corresponding to the inner side surface of the top cover 11 at a higher position, and the backflow side 132 is located corresponding to the inner side surface of the bottom plate 12 at a lower position. Therefore, the recessed surface can be provided at each of the end surfaces of the first columns 111, and the protruded surface can be provided at each of the end surfaces of the second columns 121 corresponding to the recessed surfaces.

In this case, the working fluid condensed at the condensing side 131 will drop to the backflow side 132 under the force of gravity or flow along the first columns 111 and the second columns 121 to the backflow side 132. Since the first columns 111 are located corresponding to the condensing side 131 and have recessed end surfaces while the second columns 121 are located corresponding to the backflow side 132 and have protruded end surfaces, the condensed working fluid flowing toward the backflow side 132 will pass the joints between the complementary recessed and protruded end surfaces of the first columns 111 and the second columns 121 without being interrupted by the joints. Therefore, even when the heat exchanger assembly of the present invention is used in a special environment, such as an extremely low-temperature environment, the working fluid in a frozen state would not accumulate at any position when the working fluid circulates in the whole process of heat exchange.

In other operable embodiments of the present invention, the end surfaces of the first columns 111 and the end surfaces of the second columns 121 can be otherwise correspondingly stably connected to or in contact with each other in all normal conditions. However, it is understood the present invention is not particularly limited to the above described manner.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat exchanger assembly comprising at least one condenser structure; the condenser structure including:
a top cover being provided on an inner side surface of the top cover with a plurality of first columns; and
a bottom plate being provided on an inner side surface of the bottom plate with a plurality of second columns; and
the top cover and the bottom plate being closed together to define a sealed chamber between them, such that end surfaces of the first columns and the second columns are located end to end in one to one correspondence.

2. The heat exchanger assembly as claimed in claim 1, wherein the end surfaces of the first columns are respectively configured as one of a recessed surface and a protruded surface, and the end surfaces of the second columns are respectively configured as another one of the recessed and protruded surfaces complementary to the end surfaces of the first columns.

3. The heat exchanger assembly as claimed in claim 2, wherein the recessed and the protruded end surfaces of the first and the second columns have complementary profiles selected from the group consisting of curved profiles, rectangular profiles, and wedge-shaped profiles.

4. The heat exchanger assembly as claimed in claim 2, wherein the sealed chamber has a condensing side located at the inner side surface of the top cover and a backflow side located at the inner side surface of the bottom plate.

5. The heat exchanger assembly as claimed in claim 4, wherein the end surfaces of the first columns are recessed surfaces, and the end surfaces of the second columns are protruded surfaces matching the recessed surface of the end surfaces of the first columns.

6. The heat exchanger assembly as claimed in claim 1, wherein the end surfaces of the first columns are correspondingly in contact with the end surfaces of the second columns.

7. The heat exchanger assembly as claimed in claim 1, wherein the condenser structure is communicable with an evaporator via an inlet pipe and a backflow pipe.
